(19) United States
(12) Patent Application Publication
(10) Pub. No.: US 2026/0164706 A1
(43) Pub. Date: Jun. 11, 2026

(54) Semiconductor Device with Unit Transistor Cells

(71) Applicant: Silicon-Magic Semiconductor Technology (Hangzhou) Co., Ltd., Hangzhou (CN)

(72) Inventors: Baozhu Wang, Hangzhou (CN); Jiakun Wang, Hangzhou (CN)

(73) Assignee: Silicon-Magic Semiconductor Technology (Hangzhou) Co., Ltd., Hangzhou (CN)

(21) Appl. No.: 19/361,047

(22) Filed: Oct. 17, 2025

(30) Foreign Application Priority Data
Dec. 6, 2024 (CN) 2024117935005

(51) Int. Cl. H10D 30/63; H10D 62/10; H10D 64/23

(52) U.S. Cl. CPC H10D 30/63; H10D 62/102; H10D 62/126; H10D 64/2527

(57) ABSTRACT

A semiconductor device having a substrate, an epitaxial layer, body regions, source regions and source contact regions. The epitaxial layer overlies the substrate, and has a top surface and a bottom surface contacting the substrate. The body regions are disposed in the epitaxial layer and are extending along a first direction parallel to the top surface. The source regions are disposed in the body regions and are extending along the first direction. The source contact regions are disposed in the source regions along the first direction. By integrating the source contact regions in the source regions, the device cell pitch is reduced, leading to a lower on-resistance.

### CROSS-REFERENCE TO RELATED APPLICATION

This application claims the benefit of Chinese patent application No. 202411793500.5, filed on Dec. 6, 2024, which is incorporated herein by reference in its entirety.

### TECHNICAL FIELD

The present disclosure relates to semiconductor device structures and in particular to MOSFET (Metal Oxide Semiconductor Field Effect Transistor).

### BACKGROUND

FIG. 1 illustrates a cross-sectional view of a conventional planar gate MOSFET 100. As shown in FIG. 1, the MOSFET 100 includes a semiconductor layer 111 and a gate structure 112 disposed on the semiconductor layer 111. The gate structure 112 includes a gate electrode 112a and an insulating layer 112b wrapping the gate electrode 112a. The semiconductor layer 111 includes a substrate 101, an epitaxial layer 102 disposed on the substrate 101, body regions 103 positioned in the epitaxial layer 102, source regions 104 and body contact regions 105 positioned in the body regions 103. The bottom surface of the semiconductor layer 111 which is distanced from the gate structure 112 is covered by a drain electrode layer 106. The upper surface of the semiconductor layer 111, to which the source regions 104 are exposed, is covered by a source contact 107. As shown in FIG. 1, unit cell pitch L is defined by, the width Lohmic of the source contact 107, the source contact-polysilicon gate spacing Lgs, the polysilicon gate overlapped MOSFET channel spacing Loverlap, the channel length Lch, the JFET region width Ljfet, which is L=Lohmic+2Lgs+2Loverlap+2Lch+Ljfet. Currently, the lengths of the various regions have reached the limits of existing process capabilities, making it extremely difficult to further reduce the cell pitch, resulting in the inability to further lower the semiconductor device's on-resistance.

### SUMMARY

The present disclosure provides a semiconductor device with source contact regions formed in the source regions to establish an electrical connection with a source electrode layer. Along the longitudinal direction of the semiconductor device, the rows of the source contact regions and gate electrode layers are arranged in an alternating pattern. This configuration eliminates the need for the body contact regions that, in the prior art, were typically disposed along the source regions. Thereby, the cell pitch is effectively reduced, consequently lowering the on-resistance of the semiconductor device.

The embodiments of the present disclosure are directed to a semiconductor device including a substrate, an epitaxial layer, body regions, source regions and source contact regions. The epitaxial region overlies the substrate, and has a top surface and a bottom surface contacting the substrate. The body regions are disposed in the epitaxial layer and extend along a first direction parallel to the top surface. The source regions are disposed in the body regions and extend along the first direction. The source contact regions are disposed in the source regions along the first direction.

In one embodiment, in a second direction perpendicular to the first direction, the source contact regions are in rows.

In one embodiment, the semiconductor device further includes gate structures, wherein each one of the gate structures comprises: a gate oxide layer, disposed on the top surface of the epitaxial layer; and a gate electrode layer, overlying the gate oxide layer; wherein the gate structures and the rows of the source contact regions are arranged alternately in the first direction.

In one embodiment, in a second direction perpendicular to the first direction, the source contact regions are staggered.

In one embodiment, the semiconductor device further includes a gate structure. The gate structure includes a gate oxide layer and a gate electrode layer. The gate oxide layer is disposed on the top surface of the epitaxial layer. The gate electrode layer overlies the gate oxide layer. The gate oxide layer and the gate electrode layer cover the top surface except for the source contact regions and a peripheral region surrounding each source contact region, wherein the peripheral region is covered by the interlayer dielectric layer insulating the gate electrode layer and a source electrode layer.

The embodiments of the present disclosure are directed to a semiconductor device including a substrate, an epitaxial layer, body regions, source regions and source contact regions. The epitaxial layer overlies the substrate has a top surface and a bottom surface contacting the substrate. The body regions are disposed in the epitaxial layer and extend along a first direction parallel to the top surface. The source regions are disposed in the body regions and extend along the first direction. The source contact regions are disposed in the source regions along the first direction. The gate structures cover portions of the top surface of the epitaxial layer. Each one of the gate structures has a gate oxide layer and a gate electrode layer overlying the gate oxide layer. Along the first direction, the source contact regions are disposed in the source regions and are between the neighboring gate structures.

In one embodiment, each one of the gate structures has portions extending along the first direction and connects the neighboring gate structures. Each one of the portions of the gate structures is located on the top surface of the epitaxial layer between two source contact regions adjacent in the second direction.

The embodiments of the present disclosure are directed to a unit transistor cell of a semiconductor device, including a substrate, an epitaxial layer, two body regions, two source regions, at least one source contact region, a gate oxide layer, and a gate electrode layer. The epitaxial layer overlies the substrate and the epitaxial layer has a top surface and a bottom surface contacting the substrate. The two body regions are disposed in the epitaxial layer along a first direction. The body regions are stripe-shaped and are distanced from each other, forming a mesa region between the two body regions. The two source regions are disposed in the two body regions respectively along the first direction. The source regions are stripe-shaped and have a depth smaller than a depth of the body regions. The at least one source contact region is disposed in the source region in a terminal region of the unit transistor cell. The gate oxide layer covers the top surface of the epitaxial layer except for the terminal regions of the unit transistor cell. The gate electrode layer overlies the gate oxide layer.

In one embodiment, the gate oxide layer and the gate electrode layer extend along the first direction to cover portions of the terminal regions where the at least one source contact region is absent.

Those skilled in the art will recognize additional features and advantages upon reading the following detailed description, and upon viewing the accompanying drawings.

### BRIEF DESCRIPTION OF FIGURES

The present disclosure can be further understood with reference to following detailed description and appended drawings, wherein like elements are provided with like reference numerals. These drawings are only for illustration purpose, thus may only show part of the devices and are not necessarily drawn to scale. It is obvious that the drawings described below are some implementations of the present disclosure, and those skilled in the art would also obtain other drawings on the basis of these drawings, without involving any inventive skill.

FIG. 1 illustrates a cross-sectional view of a prior art planar gate MOSFET 100.

FIG. 2 illustrates a partial top plan view of a semiconductor device 200 in accordance with an embodiment of the present disclosure.

FIG. 3 illustrates a first cross-sectional view 300 of the semiconductor device 200 along line AA' in FIG. 2 in accordance with an embodiment of the present disclosure.

FIG. 4 illustrates a second cross-sectional view 400 of the semiconductor device 200 along line BB' in FIG. 2 in accordance with an embodiment of the present disclosure.

FIG. 5 illustrates a second cross-sectional view 500 of the semiconductor device 200 along line BB' in FIG. 2 in accordance with another embodiment of the present disclosure.

FIG. 6 illustrates a second cross-sectional view 600 of the semiconductor device 200 along line BB' in FIG. 2 in accordance with another embodiment of the present disclosure.

FIG. 7 illustrates a partial top plan view of a semiconductor device 700 in accordance with an embodiment of the present disclosure.

FIG. 8 illustrates a second cross-sectional view 800 of the semiconductor device 700 along line BB' in FIG. 7 in accordance with an embodiment of the present disclosure.

FIG. 9 illustrates a second cross-sectional view 900 of the semiconductor device 700 along line BB' in FIG. 7 in accordance with another embodiment of the present disclosure.

FIG. 10 illustrates a second cross-sectional view 1000 of the semiconductor device 700 along line BB' in FIG. 7 in accordance with an embodiment of the present disclosure.

FIG. 11 illustrates a partial top plan view of a semiconductor device 1100 in accordance with an embodiment of the present disclosure.

FIG. 12 illustrates a second cross-sectional view 1200 of the semiconductor device 1100 along line BB' in FIG. 11 in accordance with an embodiment of the present disclosure.

FIG. 13 illustrates a partial top plan view of a semiconductor device 1300 in accordance with an embodiment of the present disclosure.

FIG. 14 illustrates a partial top plan view of a semiconductor device 1400 in accordance with an embodiment of the present disclosure.

The use of the same reference label in different drawings indicates the same or like components.

### DETAILED DESCRIPTION

Various embodiments of the present disclosure will now be described. In the following description, some specific details, such as example circuits and example values for these circuit components, are included to provide a thorough understanding of embodiments. One skilled in the relevant art will recognize, however, that the present disclosure can be practiced without one or more specific details, or with other methods, components, materials, etc. In other instances, body-known structures, materials, processes or operations are not shown or described in detail to avoid obscuring aspects of the present disclosure.

Throughout the specification and claims, the terms “left”, “right”, “in”, “out”, “front”, “back”, “up”, “down”, “top”, “atop”, “bottom”, “on”, “over”, “under”, “above”, “below”, “vertical” and the like, if any, are used for descriptive purposes and not necessarily for describing permanent relative positions. It is to be understood that the terms so used are interchangeable under appropriate circumstances such that embodiments of the technology described herein are, for example, capable of operation in other orientations than those illustrated or otherwise described herein. The phrases “in one embodiment”, “in some embodiments”, “in one implementation”, and “in some implementations” as used includes both combinations and sub-combinations of various features described herein as body as variations and modifications thereof. These phrases used herein does not necessarily refer to the same embodiment, although it may. Those skilled in the art should understand that the meanings of the terms identified above do not necessarily limit the terms, but merely provide illustrative examples for the terms. It is noted that when an element is “connected to” or “coupled to” the other element, it means that the element is directly connected to or coupled to the other element, or indirectly connected to or coupled to the other element via another element. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

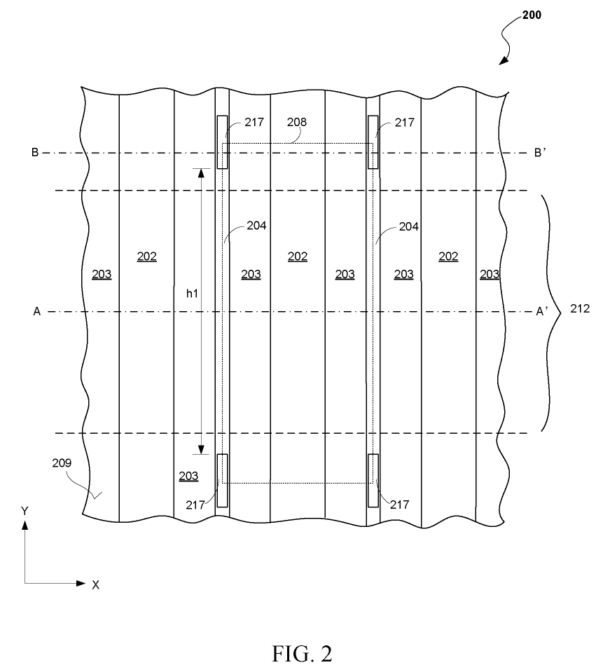

FIG. 2 illustrates a partial top plan view of a semiconductor device 200 in accordance with an embodiment of the present disclosure. As shown in FIG. 2, a unit transistor cell 208 of the semiconductor device 200 includes a mesa region 202, body regions 203, source regions 204, and source contact regions 217. The mesa region 202, the body regions 203, and the source regions 204 are arranged as parallel stripes, with longitudinal direction extending along a first direction (the y-direction as shown in FIG. 2). The body regions 203 are disposed on both sides of the mesa region 202. The source regions 204 are disposed in the body regions 203 respectively. The source contact regions 217 are disposed in the source regions 204 respectively. Along the stripe of a single source region 204, adjacent source contact regions 217 are aligned and are spaced apart from each other by a certain interval.

In the embodiment of FIG. 2, the unit transistor cell 208 of the semiconductor device 200 includes the mesa region 202, and the body regions 203 disposed on both sides of the mesa region 202. The adjacent transistor cells share the body regions 203. The source region 204 is disposed in the body region 203. The source contact regions 217 are disposed in the source region 204 and align with the source region 204 along the first direction.

The embodiment of FIG. 2 shows a partial of the top surface 209 of the epitaxial layer of the semiconductor device 200. The semiconductor device 200 includes multiple unit transistor cells 208. In the layout of the semiconductor device 200, multiple source contact regions 217 are disposed in each stripe-shape source region 204. In some embodiments, the source contact regions 217 along a source region 204 are equidistantly disposed. In some embodiments, a spacing h1 between adjacent source contact regions 217 along the stripe-shaped source region 204 is at least 0.5 μm.

FIG. 2 illustrates the plan view of the top surface 209 of the epitaxial layer of the semiconductor device 200. The area between the upper and lower dashed lines in FIG. 2 is for distributing the gate electrode layer 212. To clearly illustrate the planar structure of the top surface 209 of the epitaxial layer, various structures covering on the top surface 209 are not shown in FIG. 2. The dashed lines are symbolic and denote the positions of the gate electrode layer 212 and its underlying gate oxide layer, and are not actual physical dimensions. As shown in FIG. 2, the source contact regions are arranged in rows in a second direction (the x-direction as shown in FIG. 2) perpendicular to the first direction. The gate structures, i.e., the gate oxide layer 214 and the gate electrode layer 212, are arranged between the rows of the source contact regions in the first direction. In other words, the gate structures and the rows of the source contact regions 217 are arranged alternately in the first direction.

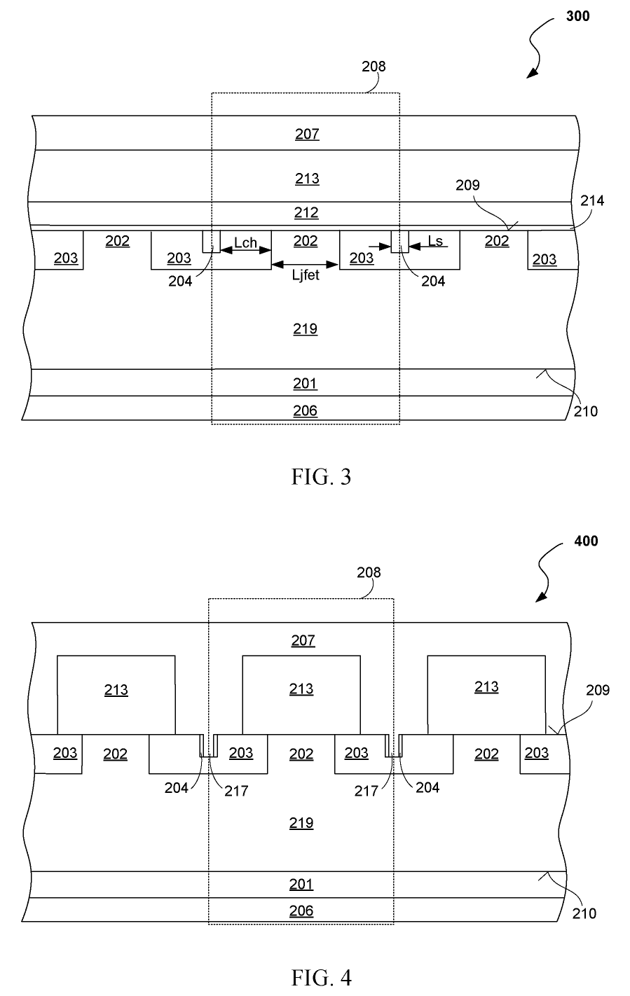

FIG. 3 illustrates a first cross-sectional view 300 of the semiconductor device 200 along line AA' in FIG. 2 in accordance with an embodiment of the present disclosure. The first cross-sectional view 300 is parallel to the second direction (the x-direction as shown in FIG. 2) and is perpendicular to the first direction (the y-direction as shown in FIG. 2). As shown in FIG. 3, the semiconductor device 200 includes a substrate 201, an epitaxial layer 219, the body regions 203, the source regions 204, a gate oxide layer 214, the gate electrode layer 212, an interlayer dielectric layer 213, a source electrode layer 207, and a drain electrode layer 206. The epitaxial layer 219 overlies on a first surface of the substrate 201. The drain electrode layer 206 covers a second surface of the substrate 201, said first and second surfaces being opposite and parallel. The epitaxial layer 219 has opposite and parallel top surface 209 and bottom surface 210. The bottom surface 210 covers the first surface of the substrate 201. The top surface 209 is covered by the gate oxide layer 214 in the first cross-sectional view 300. The body regions 203 extend from the top surface 209 into the interior of the epitaxial layer 219. The body regions 203 are separated by the mesa regions 202 and are equidistantly arranged in the second direction. It should be understood that the mesa regions 202 are portions of the epitaxial layer 219. The source region 204 is located in the body region 203, extending from the top surface 209 into the interior of the body region 203. The bottom of the source region 204 does not reach the bottom of the body region 203, i.e., the distance from the bottom of the body region 203 to the top surface 209 is greater than the distance from the bottom of the source region 204 to the top surface 209. Both the body region 203 and the source region 204 are exposed at the top surface 209. The gate oxide layer 214 covers the top surface 209, isolating the gate electrode 212 above it from the underlying top surface 209. The gate electrode layer 212 is covered by the interlayer dielectric layer 213. The source electrode layer 207 is located on the interlayer dielectric layer 213. The gate electrode layer 212 and the source electrode layer 207 are insulated by the interlayer dielectric layer 213.

In one embodiment, the gate oxide layer 214 is made of silicon dioxide, with a thickness between 5 nm and 200 nm. In other embodiments, the gate oxide layer 214 may also be made of other insulating materials such as silicon nitride or aluminum nitride. The interlayer dielectric layer 213 may be the same insulating material as the gate oxide layer 214 or other different insulating materials. The thickness of the interlayer dielectric layer 213 is much greater than the thickness of the gate oxide layer 214.

In one embodiment, the epitaxial layer 219 is of a single conductivity type and has a substantially uniform concentration. In some embodiments, the epitaxial layer 219 includes multiple semiconductor layers having different doping concentrations. For example, the epitaxial layer 219 may include a first layer having a first doping concentration and a second layer having a second doping concentration. The first layer is located in a region below the body region at a certain distance from the bottom of the body region, and the second layer is located above the first layer. The first doping concentration is less than the second doping concentration. In other embodiments, the epitaxial layer 219 may also include more layers with different doping concentrations.

In one embodiment, the substrate 201, the epitaxial layer 219, and the source regions 204 have a first doping type, and the body regions 203 has a second doping type. In one embodiment, the first doping type is n-type doping, and the second conductivity type is p-type doping. It should be understood that in other embodiments, the first doping type may be p-type doping, and the second doping type may be n-type doping. In one embodiment, the doping concentration of the substrate 201 is greater than the doping concentration of the epitaxial layer 219.

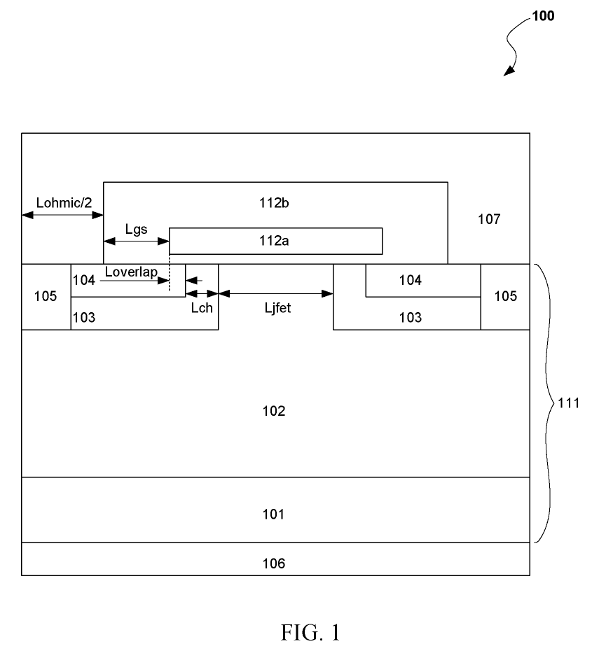

In the embodiment of FIG. 3, the upper portions of the mesa regions 202 near the gate oxide layer 214 form the JFET regions. As can be seen from FIG. 3, the body contact region 105 present in the conventional planar gate MOSFET 100 is absent. Consequently, the cell pitch of a unit transistor cell of the semiconductor device 200 is L = Ls + 2Lch + Ljfet. Compared to the prior art device, elimination of the body contact region in the semiconductor device 200 of the present disclosure also omits the need for the corresponding ohmic contact region (contact between the source contact and the body contact region/source region). Therefore, in the second direction, i.e., perpendicular to the lengthwise direction of the source region 204, there is no need for the ohmic contact region (Lohmic), the overlap region between the gate oxide and the source region (Loverlap), and the thickness due to the interlayer dielectric layer sidewall (Lgs) as shown in FIG. 1. Furthermore, the width of the source region could also be significantly reduced. Thus, the cell pitch is greatly reduced, allowing the semiconductor device 200 to have a smaller device area.

FIG. 4 illustrates a second cross-sectional view 400 of the semiconductor device 200 along line BB' in FIG. 2 in accordance with an embodiment of the present disclosure. As shown in FIG. 4, the second cross-sectional view 400 includes the substrate 201, the epitaxial layer 219, the body regions 203, the source regions 204, the interlayer dielectric layer 213, the source electrode layer 207, and the drain electrode layer 206. In the second cross-sectional view 400, the source electrode layer 207 extends downward through openings in the interlayer dielectric layer 213, penetrates the source region 204, and reaches the body region 203. The source electrode layer 207 contacts both the source region 204 and the underlying portion of the body region 203, thereby electrically connecting the potentials of the source region 204 and the body region 203 to that of the source electrode layer 207. In the embodiment of FIGS. 2-4, the portions of the source electrode layer 207 formed in the source regions 204 constitutes the source contact regions 217. That is, the source contact region 217 is an integral part of the source electrode layer 207. In other words, to connect the potential of the body region 203 to a source potential of the device (i.e., the potential of the source electrode layer), multiple openings are formed in the interlayer dielectric layer 213. The source electrode layer 207 partially extends downward to fill these openings in the interlayer dielectric layer 213. Alternatively, in some embodiments, conductive via structures may be used to fill the openings in the interlayer dielectric layer 213, embed into the source region 204, penetrate through the source regions 204, and reach the underlying body regions 203. Therefore, in some embodiments, the source contact region 217 may be a via connection structure. The source contact region 217 contacts both the source region 204 and the body region 203, electrically connecting them to the source electrode layer 207, and consequently, to the source potential of the semiconductor device 200.

Different from the first cross-sectional view 300, the source contact regions 217 is disposed in the source region 204 in the second cross-sectional view 400. Furthermore, the gate oxide layer 214 and the gate electrode layer 212 are absent in the second cross-sectional view 400. Referring to FIG. 2, along the longitudinal direction of the unit transistor cell 208, the source contact regions 217 are disposed in specific portions of the stripe-shaped source regions 204, at the terminal regions of the unit transistor cell 208. The source contact regions 217 serve to connect portions of the body regions 203 and portions of the source regions 204 to the source electrode layer 207. To avoid short between the source potential and the gate potential, the gate oxide layer 214 and the gate electrode layer 212 are absent from terminal regions where the source contact regions 217 are disposed.

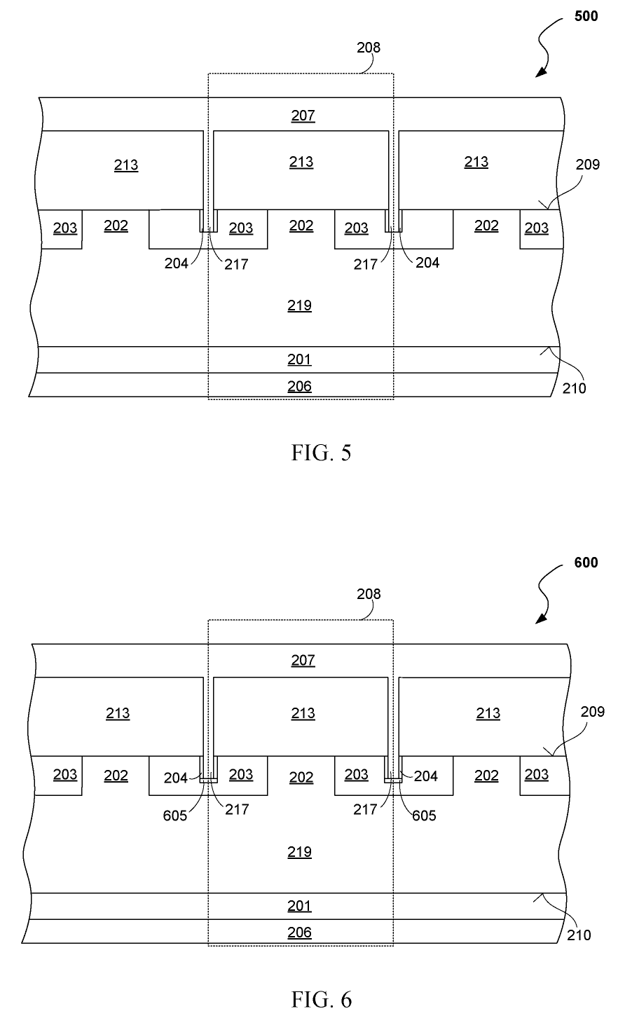

FIG. 5 illustrates a second cross-sectional view 500 of the semiconductor device 200 along line BB' in FIG. 2 in accordance with another embodiment of the present disclosure. As shown in FIG. 5, the second cross-sectional view 500 includes the substrate 201, the epitaxial layer 219, the body regions 203, the source regions 204, the interlayer dielectric layer 213, the source electrode layer 207, and the drain electrode layer 206. In the second cross-sectional view 500, the source electrode layer 207 extends downward through openings in the interlayer dielectric layer 213, penetrates the source region 204, and reaches the body region 203. The source electrode layer 207 contacts both the source region 204 and the underlying portion of the body region, thereby electrically connecting the potential of the source region 204 and the body region 203 to that of the source electrode layer. Different from the embodiment of FIG. 4, the opening in the interlayer dielectric layer 213 that accommodates the source electrode layer 207 has the same width as the corresponding opening in the source region 204 in the embodiment of FIG. 5. This configuration not only allows the width of the body region 203 to be minimized to the limit permitted by the fabrication process, but also enables the use of a single mask to form both the opening in the interlayer dielectric layer 213 and the opening in the source region 204 for the source electrode layer 207, thereby saving process steps and reducing cost.

FIG. 6 illustrates a second cross-sectional view 600 of the semiconductor device 200 along line BB' in FIG. 2 in accordance with another embodiment of the present disclosure. As shown in FIG. 6, the second cross-sectional view 600 includes the substrate 201, the epitaxial layer 219, the body regions 203, body contact regions 605, the source regions 204, the interlayer dielectric layer 213, the source electrode layer 207, and the drain electrode layer 206. In the second cross-sectional view 600, the source electrode layer 207 extends downward through openings in the interlayer dielectric layer 213, with portions, i.e., source contact regions 217, penetrating the source regions 204, and reaching the body contact regions 605 under the source regions 204 to form ohmic contacts. In some embodiments, the body contact regions 605 are disposed under portions of each single stripe-shaped source region 204. In other embodiments, the body contact regions 605 are disposed under portions of selected stripe-shaped source regions 204. In yet other embodiments, the body contact regions 605 may be disposed at the whole bottoms of all stripe-shaped source regions 204.

It should be understood that in the embodiments of FIGS. 2-6, the source contact regions 217 embedded in the source regions 204 may also be arranged in a staggered pattern along the second direction, rather than being aligned in rows.

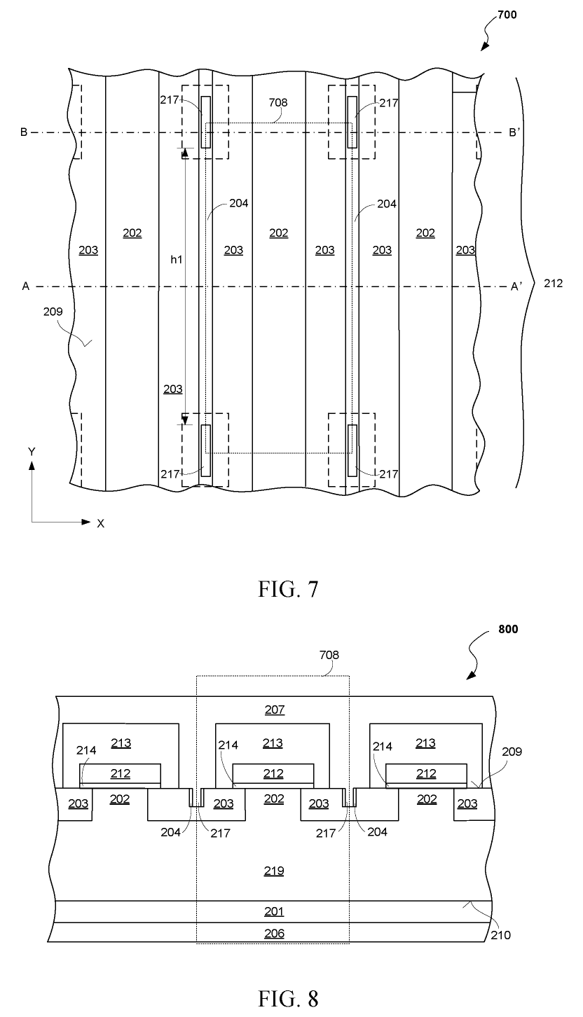

FIG. 7 illustrates a partial top plan view of a semiconductor device 700 in accordance with an embodiment of the present disclosure. As shown in FIG. 7, a unit transistor cell 708 of the semiconductor device 700 includes a mesa region 202, body regions 203, source regions 204 and source contact regions 217. The mesa region 202, the body regions 203, and the source regions 204 are arranged as parallel stripes, with longitudinal direction extending along the first direction (the y-direction as shown in FIG. 7). The body region 203 is disposed on both sides of the mesa region 202. The source regions 204 are disposed in the body regions 203. The source contact regions 217 are disposed in portions of the source regions 204. In the layout of the semiconductor device 700, multiple source contact regions 217 are disposed in a stripe-shape source region 204. In some embodiments, the source contact regions 217 along a source region 204 are equidistantly disposed. In some embodiments, a spacing h1 between adjacent source contact regions 217 along the stripe-shaped source region 204 is at least 0.5 μm.

Different from the FIG. 2 embodiment, in the FIG. 7 embodiment, in the terminal regions of the unit cell 708 along the first direction, the gate oxide layer 214 and the gate electrode layer 212 extend along the first direction into the region between two adjacent source contact regions 217, covering both the mesa region 202 between the adjacent body regions and portions of the adjacent body regions on both sides of the mesa region 202, thereby increasing the area available for the device's conduction current. In other words, the gate oxide layer 214 and the gate electrode layer 212 cover all regions except the source contact region 217 and its immediate surrounding area, i.e. the peripheral region surrounding each source contact region 217, which is covered by the interlayer dielectric layer insulating the gate electrode layer 212 and the source electrode layer 207.

In the embodiment of FIG. 7, the cross-sectional view taken along line AA' is similar to the cross-sectional view 300 of the semiconductor device 200. Therefore, for brevity, it will not be described here.

FIG. 8 illustrates a second cross-sectional view 800 of the semiconductor device 700 along line BB' in FIG. 7 in accordance with an embodiment of the present disclosure. As shown in FIG. 8, the second cross-sectional view 800 includes the substrate 201, the epitaxial layer 219, the body regions 203, the source regions 204, the gate oxide layer 214, the gate electrode layer 212, the interlayer dielectric layer 213, the source electrode layer 207, and the drain electrode layer 206. Different from the second cross-sectional view 400 in FIG. 4, under the interlayer dielectric layer 213, the mesa region 202 and the immediate surrounding area, i.e., portions of the body regions 203, are covered by the gate structure, i.e., the gate oxide layer 214 and the gate electrode layer 212. The gate structures induce channels in the body region portions near the sidewalls of the mesa regions 202, leading to a higher device current density.

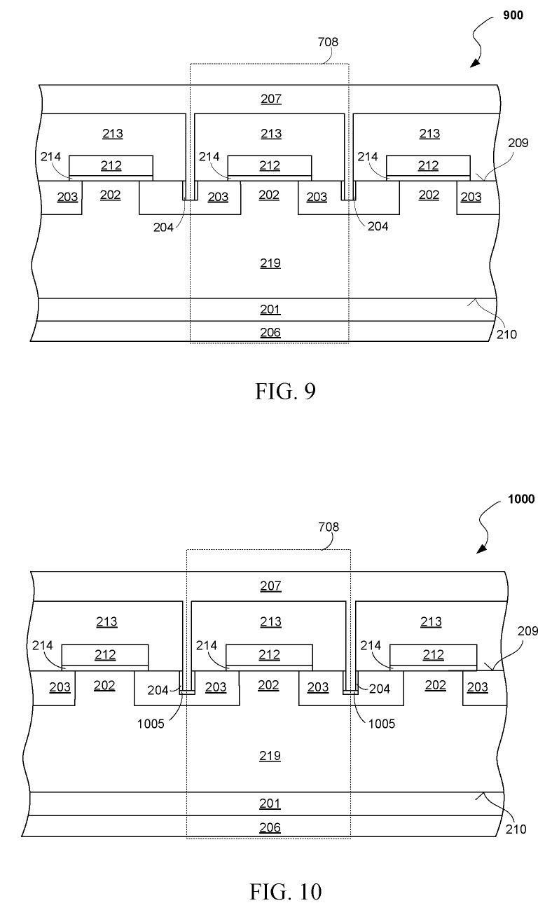

FIG. 9 illustrates a second cross-sectional view 900 of the semiconductor device 700 along line BB' in FIG. 7 in accordance with another embodiment of the present disclosure. As shown in FIG. 9, the second cross-sectional view 900 includes the substrate 201, the epitaxial layer 219, the body regions 203, the source regions 204, the gate oxide layer 214, the gate electrode layer 212, the interlayer dielectric layer 213, the source electrode layer 207, and the drain electrode layer 206. In the second cross-sectional view 900, the source electrode layer 207 extends downward through openings in the interlayer dielectric layer 213, penetrates the source region 204, and reaches the body region 203. Portions of the source electrode layer 207 in the source regions 204 constitute the source contact regions 217. The source contact regions 217 contact both the source regions 204 and the underlying portions of the body regions 203, thereby electrically connecting the potential of the source region 204 and the body region 203 to that of the source electrode layer 207. Different from the embodiment of FIG. 8, the opening in the interlayer dielectric layer 213 that accommodates the source contact region 217 has the same width as the corresponding opening in the source region 204 as in the embodiment of FIG. 5. This configuration not only allows the width of the body region 203 to be minimized to the limit permitted by the fabrication process, but also enables the use of a single mask to form both the opening in the interlayer dielectric layer 213 and the opening in the source region 204 for the source electrode layer 207, thereby saving process steps and reducing cost.

Different from the second cross-sectional view 500 in FIG. 5, under the interlayer dielectric layer 213, the mesa region 202 and the immediate surrounding area, i.e., portions of the body regions 203, are covered by the gate structure, i.e., the gate oxide layer 214 and the gate electrode layer 212. The gate structures induce channels in the body region portions near the sidewalls of the mesa regions 202, leading to a higher device current density.

FIG. 10 illustrates a second cross-sectional view 1000 of the semiconductor device 700 along line BB' in FIG. 7 in accordance with an embodiment of the present disclosure. As shown in FIG. 10, the cross-sectional view 1000 includes the substrate 201, the epitaxial layer 219, the body regions 203, the body contact regions 1005, the source regions 204, the interlayer dielectric layer 213, the source electrode layer 207, and the drain electrode layer 206. In the second cross-sectional view 1000, the source electrode layer 207 extends downward through openings in the interlayer dielectric layer 213, with portions, i.e., source contact regions 217 penetrating the source regions 204, and reaching the body contact regions 1005 under the source region 204 to form ohmic contact. In some embodiments, the body contact regions 1005 are disposed under portions of each single stripe-shaped source region 204. In other embodiments, the body contact regions 1005 are disposed under portions of selected stripe-shaped source regions 204. In yet other embodiments, the body contact regions 1005 may be disposed at the whole bottoms of all stripe-shaped source regions 204.

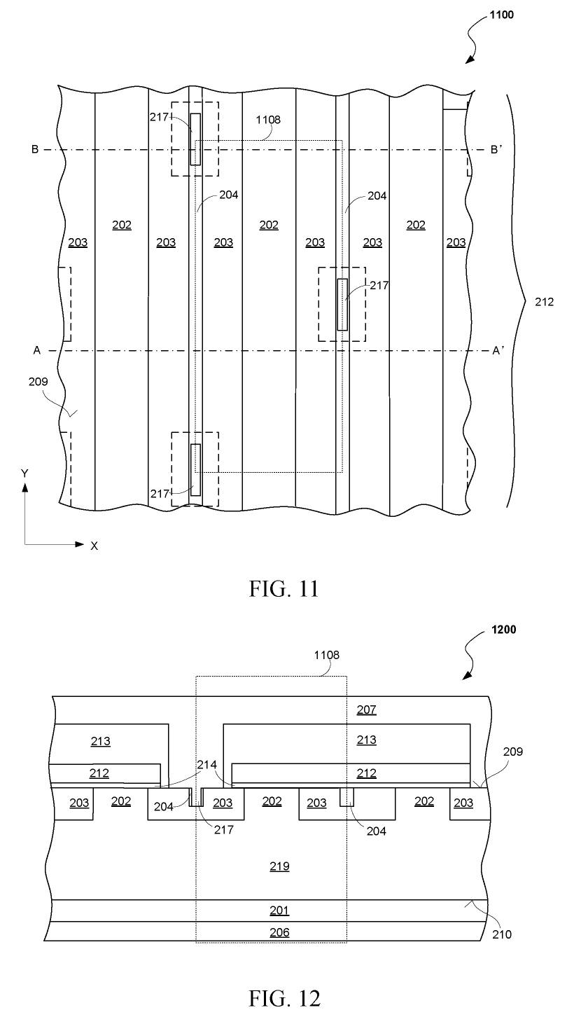

FIG. 11 illustrates a partial top plan view of a semiconductor device 1100 in accordance with an embodiment of the present disclosure. As shown in FIG. 11, a unit transistor cell 1108 of the semiconductor device 1100 includes a mesa region 202, body regions 203, source regions 204, and source contact regions 217. The mesa region 202, the body regions 203, and the source regions 204 are arranged as parallel stripes, with longitudinal direction extending along a first direction (the y-direction as shown in FIG. 2). The body regions 203 are disposed on both sides of the mesa region 202. The source regions 204 are disposed in the body regions 203. The source contact regions 217 are disposed in the source regions 204.

Different from the embodiments of FIGS. 2 and 7, in the embodiment of FIG. 11, the source contact regions 217 embedded in the source regions 204 are arranged in a staggered pattern along the second direction, rather than being aligned in rows.

In the embodiment of FIG. 11, the cross-sectional view taken along line AA' is similar to the cross-sectional view 300 of the semiconductor device 200. Therefore, for brevity, it will not be described here.

FIG. 12 illustrates a second cross-sectional view 1200 of the semiconductor device 1100 along line BB' in FIG. 11 in accordance with an embodiment of the present disclosure. As shown in FIG. 12, the second cross-sectional view 1200 includes the substrate 201, the epitaxial layer 219, the body regions 203, the source regions 204, the gate oxide layer 214, the gate electrode layer 212, the interlayer dielectric layer 213, the source contact regions 207, and the drain electrode layer 206. In the second cross-sectional view 1200, the source electrode layer 207 extends downward through openings in the interlayer dielectric layer 213, penetrates the source region 204, and reaches the body region 203. The source electrode layer 207 contacts both the source region 204 and the underlying portion of the body region, thereby electrically connecting the potential of the source region 204 and the body region 203 to that of the source electrode layer 207. The portion of the source electrode layer 207 formed in the source region 204 constitutes the source contact region 217. That is, the source contact region 217 is an integral part of the source electrode layer 207.

In some embodiments, the embodiment of FIG. 12 incorporates the body contact region from the aforementioned embodiments. The body contact region is positioned at the bottom of the source region, connects the body region 203 and the source region 204, and is configured to interface with the source contact region 217, thereby reducing the contact resistance between the source contact region 217 and both the body region 203 and the source region 204.

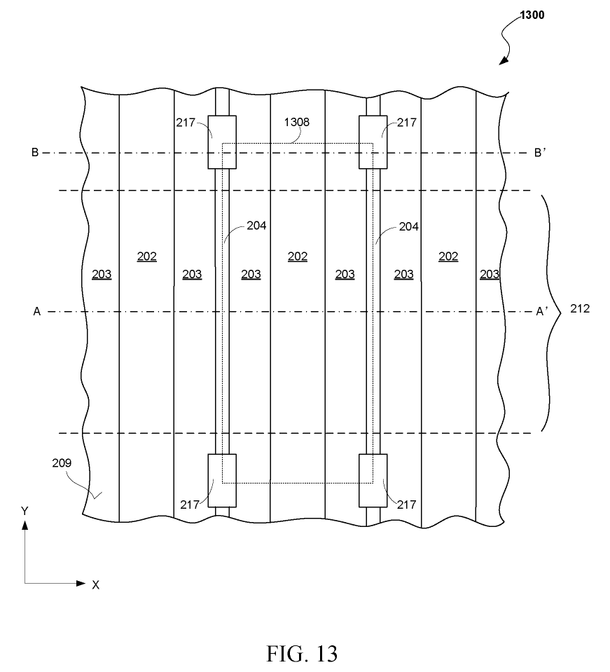

FIG. 13 illustrates a partial top plan view of a semiconductor device 1300 in accordance with an embodiment of the present disclosure. Compared to the embodiment of FIG. 2, in the embodiment of FIG. 13, the source contact region 217 has a greater width in the second direction than the source region 204 in the same direction, i.e., the source contact region 217 is wider than the source region 204. This configuration advantageously increases the area of the source contact region, thereby enhancing the current handling capability of the semiconductor device 1300. It should be understood that, to further increase the current channel of the device and reduce its on-resistance, the gate oxide layer 214 and the gate electrode layer 212 may, in some embodiments, be extended in the first direction into the area between adjacent source contact regions 217 based on the structure of FIG. 13, i.e., the coverage area of the gate oxide layer 214 and the gate electrode layer 212 on the top surface 209 of the epitaxial layer may be configured as shown in FIG. 7.

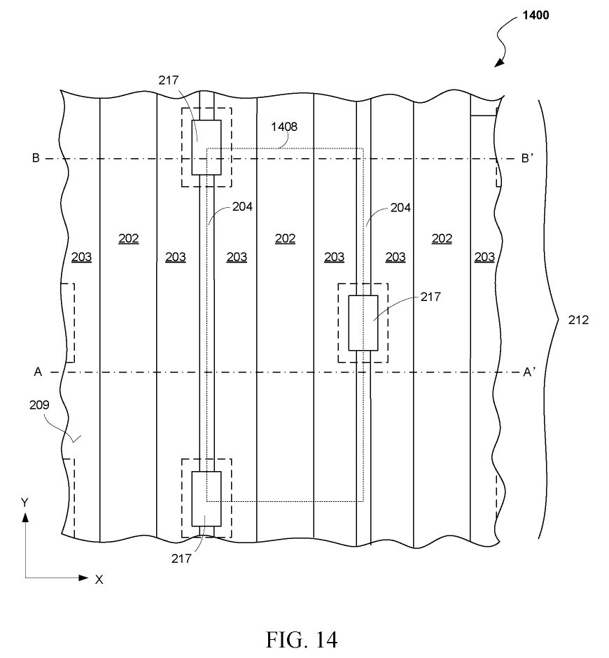

FIG. 14 illustrates a partial top plan view of a semiconductor device 1400 in accordance with an embodiment of the present disclosure. Compared to the embodiment of FIG. 11, in the embodiment of FIG. 14, the source contact region 217 has a greater width in the second direction than the source region 204 in the same direction, i.e., the source contact region 217 is wider than the source region 204. This configuration advantageously increases the area of the source contact region, thereby enhancing the current handling capability of the semiconductor device 1400.

In the embodiments of FIGS. 13 and 14, a body contact region may optionally be disposed at the bottom of the source contact region 217. The body contact region connects the source region 204 and the body region 203 and also contacts the bottom of the source contact region 217, thereby electrically coupling the potentials of the source region 204 and the body region 203 to the potential of the source electrode layer 207.

In the foregoing embodiments, the body region 203, the source contact region 217, and the source region 204 all extend vertically from the top surface 209 of the epitaxial layer 219 into its interior. The distance from the top surface 209 to the bottom of the body region 203 in the direction perpendicular to the top surface 209 is the depth of the body region 203. The distance from the top surface 209 to the bottom of the source contact region 217 in the direction perpendicular to the top surface 209 is the depth of the source contact region. The distance from the top surface 209 to the bottom of the source region 204 in the direction perpendicular to the top surface 209 is the depth of the source region 204. In some embodiments, the depth of the body region 203 is greater than the depths of the source region 204 and the source contact region 217. In some embodiments, the depth of the source region 204 is consistent with the depth of the source contact region 217. In some embodiments, the depth of the source contact region 217 is greater than the depth of the source region 204.

The present disclosure uses a MOSFET device as an example to illustrate the inventive principles. It should be understood that the present invention is equally applicable to other structures of power semiconductor devices, such as IGBTs. Those of ordinary skill in the art, upon reading the present application, can make improvements based on the device layout of the present application as needed and apply them to other structures or types of devices.

The embodiments of the present application may be used not only for devices using silicon as the semiconductor base layer, but also for devices using wide-bandgap materials, such as SiC and GaN, as the semiconductor base layer.

While various embodiments have been described above to illustrate the semiconductor device and its manufacturing method of the present disclosure, it should be understood that they have been presented by way of example only, and not limitation. Rather, the scope of the present disclosure is defined by the following claims and includes combinations and sub-combinations of the various features described above, as body as variations and modifications thereof, which would occur to persons skilled in the art upon reading the foregoing description.

1. A semiconductor device, comprising:
a substrate;
an epitaxial layer, overlying the substrate, wherein the epitaxial layer has a top surface and a bottom surface contacting the substrate;
body regions, disposed in the epitaxial layer and extending along a first direction parallel to the top surface;
source regions, disposed in the body regions and extending along the first direction; and
source contact regions, disposed in the source regions along the first direction.

2. The semiconductor device of claim 1, wherein in a second direction perpendicular to the first direction, the source contact regions are in rows.

3. The semiconductor device of claim 1, further comprising gate structures, wherein each one of the gate structures comprises:
a gate oxide layer, disposed on the top surface of the epitaxial layer; and
a gate electrode layer, overlying the gate oxide layer;
wherein the gate structures and the rows of the source contact regions are arranged alternately in the first direction.

4. The semiconductor device of claim 1, wherein in a second direction perpendicular to the first direction, the source contact regions are staggered.

5. The semiconductor device of claim 1, further comprising a gate structure, wherein the gate structure comprises:
a gate oxide layer, disposed on the top surface of the epitaxial layer; and
a gate electrode layer, overlying the gate oxide layer;
wherein the gate oxide layer and the gate electrode layer cover the top surface except for the source contact regions and a peripheral region surrounding each source contact region, wherein the peripheral region is covered by the interlayer dielectric layer insulating the gate electrode layer and a source electrode layer.

6. The semiconductor device of claim 1, wherein the source contact regions extend from the top surface into the epitaxial layer, and wherein the device further comprises body contact regions located at bottoms of the source contact regions, and contacting the source contact regions.

7. The semiconductor device of claim 1, wherein within each one of the source regions, the source contact regions are equidistantly spaced along the first direction.

8. The semiconductor device of claim 1, wherein within each one of the source regions, the source contact regions are equidistantly spaced along the first direction, and wherein a distance between adjacent source contact regions along the first direction is at least 0.5 μm.

9. The semiconductor device of claim 1, wherein a width of the source contact region in a second direction is substantially equal to a width of the source region in the second direction, and wherein the second direction is perpendicular to the first direction.

10. The semiconductor device of claim 1, wherein a width of the source contact region in a second direction is greater than a width of the source region in the second direction, and wherein the second direction is perpendicular to the first direction.

11. The semiconductor device of claim 1, wherein a width of the source contact region in a second direction is less than a width of the source region in the second direction, and wherein the second direction is perpendicular to the first direction.

12. The semiconductor device of claim 1, wherein a depth of the source contact region is greater than a depth of the source region.

13. The semiconductor device of claim 1, wherein a depth of the source contact region is substantially equal to a depth of the source region.

14. A semiconductor device, comprising:
a substrate;
an epitaxial layer, overlying the substrate, wherein the epitaxial layer havs a top surface and a bottom surface contacting the substrate;
body regions, disposed in the epitaxial layer and extending along a first direction parallel to the top surface;
source regions, disposed in the body regions and extending along the first direction;
source contact regions, disposed in the source regions along the first direction; and
gate structures, covering portions of the top surface of the epitaxial layer, wherein each one of the gate structures has a gate oxide layer and a gate electrode layer overlying the gate oxide layer;
wherein along the first direction, the source contact regions are disposed in the source regions and are between the neighboring gate structures.

15. The semiconductor device of claim 14, wherein each one of the gate structures has portions extending along the first direction and connects the neighboring gate structures, wherein each one of the portions of the gate structures is located on the top surface of the epitaxial layer between two source contact regions adjacent in the second direction.

16. The semiconductor device of claim 14, further comprising:
body contact regions, located at bottoms of the source contact regions, and contacting the source contact regions.

17. The semiconductor device of claim 14, further comprising:
a source electrode layer, connected to the source contact regions; and
a body electrode layer, overlying the substrate;
wherein the source electrode layer overlies the gate structures and portions of the top surface of the epitaxial layer uncovered by the gate structures, and wherein the source electrode layer and the gate structures are insulated by an interlayer dielectric layer.

18. A unit transistor cell of a semiconductor device, comprising:
a substrate;
an epitaxial layer, overlying the substrate, wherein the epitaxial layer has a top surface and a bottom surface contacting the substrate;
two body regions, disposed in the epitaxial layer along a first direction, wherein the body regions are stripe-shaped and are distanced from each other, forming a mesa region between the two body regions;
two source regions, disposed in the two body regions respectively along the first direction, wherein the source regions are stripe-shaped and have a depth smaller than a depth of the body regions;
at least one source contact region, disposed in the source region in a terminal region of the unit transistor cell;
a gate oxide layer, covering the top surface of the epitaxial layer except for the terminal regions of the unit transistor cell; and
a gate electrode layer, overlying the gate oxide layer.

19. The unit transistor cell of the semiconductor device of claim 18, wherein the gate oxide layer and the gate electrode layer extend along the first direction to cover portions of the terminal regions where the at least one source contact region is absent.

20. The unit transistor cell of the semiconductor device of claim 18, further comprising at least one body contact region located at a bottom of the at least one source contact region, and contacting the at least one source contact region.
